(19) United States
(12) Patent Application Publication
(10) Pub. No.: US 2011/0248271 A1
(43) Pub. Date: Oct. 13, 2011

(54) THIN FILM TRANSISTOR AND DISPLAY DEVICE HAVING THE SAME

(75) Inventors: Byoung-Kwon CHOO, Yongin-City (KR); Kyu-Sik Cho, Yongin-City (KR); Won-Kyu Lee, Yongin-City (KR); Yong-Hwan Park, Yongin-City (KR); Sang-Ho Moon, Yongin-City (KR); Min-Chul Shin, Yongin-City (KR); Tae-Hoon Yang, Yongin-City (KR); Joon-Hoo Choi, Yongin-City (KR); Bo-Kyung Choi, Yongin-City (KR); Yun-Gyu Lee, Yongin-City (KR)

(73) Assignee: Samsung Mobile Display Co., Ltd., Yongin-City (KR)

(21) Appl. No.: 13/084,965

(22) Filed: Apr. 12, 2011

(30) Foreign Application Priority Data
Apr. 12, 2010 (KR) 10-2010-0033523

(51) Int. Cl. H01L 29/04

(52) U.S. Cl. 257/59; 257/72; 257/E29.003

(57) ABSTRACT

The described technology relates generally to a thin film transistor comprising a gate electrode, a semiconductor layer and source/drain electrode, wherein the source/drain electrode is disposed in a range of a region in which the semiconductor layer is formed. Therefore, the present embodiments can provide a thin film transistor in which reliability is excellent because a change amount of threshold voltage is small.

### CROSS-REFERENCE TO RELATED APPLICATIONS

This application claims priority to and the benefit of Korean Patent Application No. 10-2010-0033523 filed in the Korean Intellectual Property Office on Apr. 12, 2010, the entire contents of which are incorporated herein by reference.

### BACKGROUND

1. Field

The described technology relates generally to a thin film transistor and a display device that includes the same, and more particularly, to a thin film transistor in which reliability is excellent because the change in amount of threshold voltage is small.

2. Description of the Related Technology

A thin film transistor is generally provided with a semiconductor layer, a gate electrode, a source electrode and a drain electrode, and the semiconductor layer is provided with a source region, a drain region and a channel region that is provided between the source and drain regions. In addition, the semiconductor layer may comprise polysilicon or amorphous silicon, and since the electron mobility of the polysilicon is higher than that of the amorphous silicon, currently, the polysilicon is mainly applied.

The polysilicon thin film transistor is classified into a top gate type in which a gate electrode is disposed on a channel region of a semiconductor layer and a bottom gate type in which a gate electrode is disposed under the semiconductor layer.

The bottom gate type thin film transistor has merits in that a manufacturing process is simple and an interface between the gate insulating layer and the channel region is not exposed, but in terms of the structure of the element, a MIM (Metal-Insulator-Metal) structure exists in the element by a layered structure of the gate electrode, the gate insulating layer and the gate electrode, and this portion has reliability problems because of a charge trap into insulator according to application of the gate voltage.

The above information disclosed in this Background section is only for enhancement of understanding of the background of the described technology and therefore it may contain information that does not form the prior art that is already known in this country to a person of ordinary skill in the art.

### SUMMARY OF CERTAIN INVENTIVE ASPECTS

The described technology has been made in an effort to provide a thin film transistor in which reliability is excellent because a MIM (Metal-Insulator-Metal) structure is not included in an element.

Therefore, it is another object of the present embodiments to provide a thin film transistor in which a change amount of threshold voltage is small.

An exemplary embodiment provides a thin film transistor comprising a gate electrode, a semiconductor layer and source/drain electrode, wherein the source/drain electrode is disposed in a range of a region in which the semiconductor layer is formed.

Another embodiment provides a thin film transistor that comprises a substrate; a gate electrode that is disposed on an upper portion of the substrate; a gate insulating layer that is disposed on the gate electrode; a semiconductor layer that is disposed on the gate insulating layer; source/drain regions that are disposed in a predetermined region of an upper portion of the semiconductor layer; source/drain electrodes that are electrically connected to the source/drain regions, wherein the semiconductor layer is inserted into all regions between the gate electrode and the source/drain electrode.

Another embodiment provides a thin film transistor that comprises a substrate; source/drain electrodes that are disposed on an upper portion of the substrate; source/drain regions that are disposed on the source/drain electrodes; a semiconductor layer that is disposed on upper portions of the source/drain regions; a gate insulating layer that is disposed on an front surface of the substrate that includes the semiconductor layer; and a gate electrode that is disposed on the gate insulating layer, wherein the semiconductor layer is inserted into all regions between the gate electrode and the source/drain electrodes.

Yet another embodiment provides a display device that comprises the thin film transistor.

Therefore, the present embodiments can provide a thin film transistor in which reliability is excellent because a MIM (Metal-Insulator-Metal) structure is not included in an element.

In addition, the present embodiments can provide a thin film transistor in which a change amount of threshold voltage is small.

### BRIEF DESCRIPTION OF THE DRAWINGS

FIG. 1A is a plan view that illustrates a bottom gate type thin film transistor that has a general structure;

FIG. 1B is a cross-sectional view that is taken along the line A-A of FIG. 1A;

FIG. 1C is a cross-sectional view that is taken along the line B-B of FIG. 1A;

FIG. 2A is a plan view that illustrates a bottom gate type thin film transistor according to the first exemplary embodiment;

FIG. 2B is a cross-sectional view that is taken along the line A-A of FIG. 2A;

FIG. 2C is a cross-sectional view that is taken along the line B-B of FIG. 2A;

FIG. 3 is a cross-sectional view of an organic light emitting diode (OLED) display that includes a bottom gate type thin film transistor according to the first exemplary embodiment;

FIG. 4 is an exemplary variation of a bottom gate type thin film transistor according to the first exemplary embodiment;

FIG. 5A is a cross-sectional view that illustrates a bottom gate type thin film transistor according to the second exemplary embodiment;

FIG. 5B is a cross-sectional view of an organic light emitting diode (OLED) display that includes a bottom gate type thin film transistor according to the second exemplary embodiment;

FIG. 6A is a plan view that illustrates a bottom gate type thin film transistor according to the third exemplary embodiment;

FIG. 6B is a cross-sectional view that is taken along the line C-C of FIG. 6A;

FIG. 7 is a cross-sectional view that illustrates a staggered type thin film transistor according to the fourth exemplary embodiment;

FIG. 8 is a graph that illustrates a change in threshold voltage (Vth) according to a change in source/drain current (Ids); and

FIG. 9 is a graph that illustrates a change in threshold voltage (Vth) according to time (s).

### DETAILED DESCRIPTION OF CERTAIN INVENTIVE EMBODIMENTS

Objects, technical constitution and effects of the present embodiments will be described more fully hereinafter with reference to the accompanying drawings, in which exemplary embodiments. In addition, in the drawings, the length and thickness of layers, regions, etc., may be exaggerated for ease of description. Like reference numerals designate like elements throughout the specification.

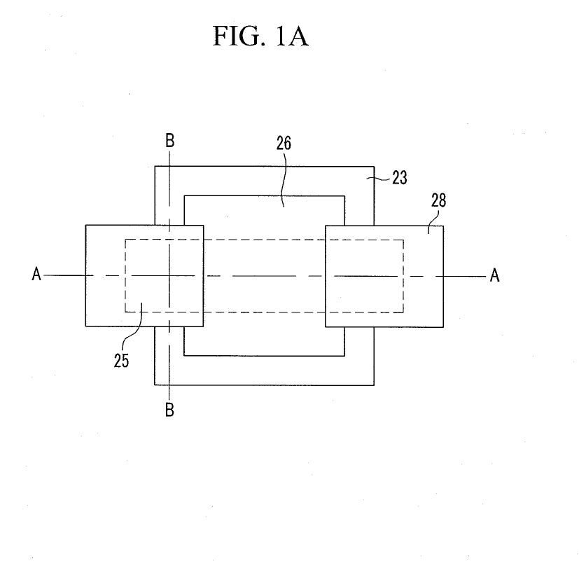

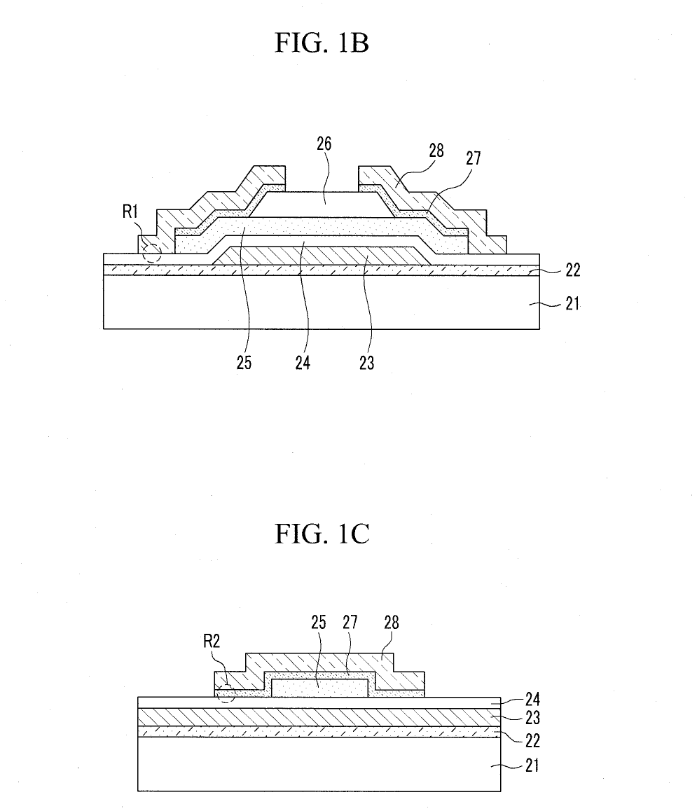

FIG. 1A is a plan view that illustrates a bottom gate type thin film transistor that has a general structure, FIG. 1B is a cross-sectional view that is taken along the line A-A of FIG. 1A, and FIG. 1C is a cross-sectional view that is taken along the line B-B of FIG. 1A.

Referring to FIG. 1A to FIG. 1C, after the buffer layer 22 is formed on the insulation substrate 21 such as, for example, glass or plastic and the metallic material is formed on the front surface of the substrate, it is patterned to form the gate electrode 23.

The gate insulating layer 24 that comprises a single layer or a multilayer of silicon oxide film or silicon nitride film is formed on the front surface of the substrate.

After the amorphous silicon layer is deposited on the front surface of the substrate, it is patterned to form the amorphous silicon layer pattern 25.

After an insulation film is formed on the front surface of the substrate, it is patterned to form an etch stopper 26 from the amorphous silicon layer pattern to the upper portion of the channel region.

After the amorphous silicon layer into which the high concentration impurity is injected is formed on the front surface of the substrate, it is patterned by using the photoresist pattern and the etch stopper to define a source/drain region by forming the amorphous silicon layer pattern 27 into which the high concentration impurity is injected.

After the conductive metal is deposited on the front surface of the substrate, the conductive metal is patterned by using the photoresist pattern and the etch stopper to accomplish a bottom gate type thin film transistor by forming the source/drain electrode 28.

However, the bottom gate type thin film transistor that has the general structure, as shown in the R1 region of FIG. 1B and the R2 region of FIG. 1C, has a problem in terms of reliability because the MIM (Metal-Insulator-Metal) structure that is constituted by the layered structure of the gate electrode 23, gate insulating layer 24 and source/drain electrode 28 exists in the element, and in the case of when gate voltage is applied to the this portion, charge trap and the like occur in the gate insulating layer.

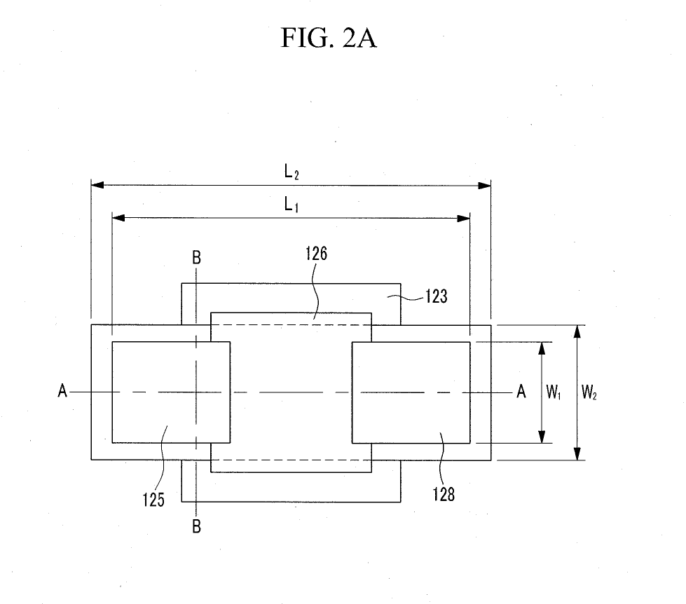

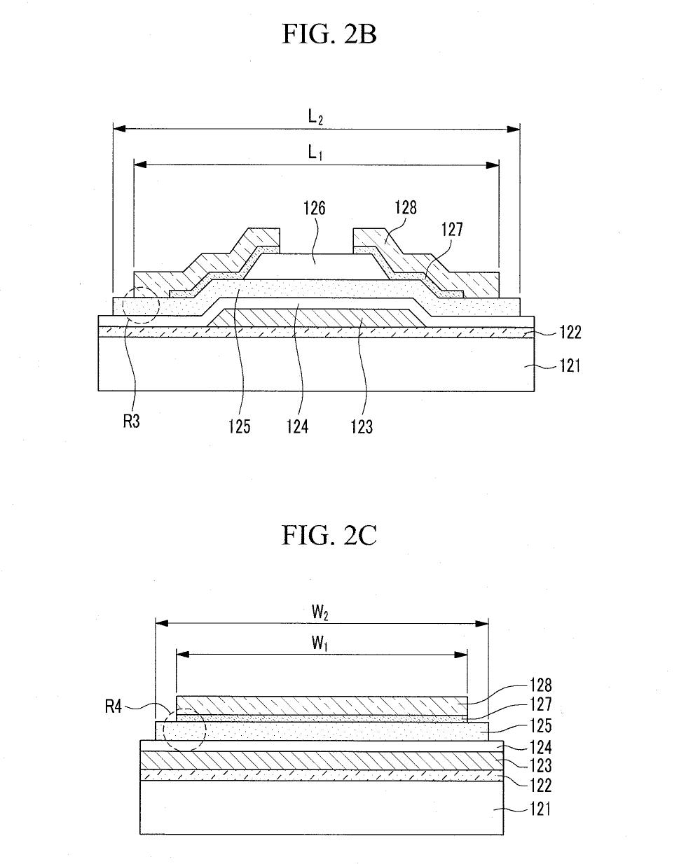

FIG. 2A is a plan view that illustrates a bottom gate type thin film transistor according to the first exemplary embodiment, FIG. 2B is a cross-sectional view that is taken along the line A-A of FIG. 2A, and FIG. 2C is a cross-sectional view that is taken along the line B-B of FIG. 2A.

Referring to FIG. 2A to FIG. 2C, after the buffer layer 122 is formed on the transparent insulation substrate 121 such as glass or plastic and the gate electrode formation material is formed on the buffer layer, it is patterned to form the gate electrode 123. The buffer layer functions to prevent diffusion of moisture of impurity that is generated in the lower substrate.

The gate insulating layer 124 that comprises a single layer or a multilayer of silicon oxide film or silicon nitride film is formed on the substrate on which the gate electrode 123 is formed, and the amorphous silicon layer (not shown) is formed on the gate insulating layer. The amorphous silicon layer may be formed by using a Chemical Vapor Deposition or Physical Vapor Deposition. In addition, when the amorphous silicon layer is formed or after the amorphous silicon layer is formed, the dehydrogenation treatment process is performed and a process for lowering the concentration of hydrogen may be performed.

The polysilicon layer (not shown) is formed by crystallizing the amorphous silicon layer, and the semiconductor layer 125 is formed by patterning the polysilicon layer.

As the method for crystallizing the amorphous silicon by using the polysilicon, there are solid phase crystallization, excimer laser crystallization, metal induced crystallization and metal induced lateral crystallization, the solid phase crystallization is a method in which the amorphous silicon layer is annealed at the temperature of about 700° C. or less that is the deformation temperature of the glass that is the material forming the substrate of the display element that uses the thin film transistor for several hours to several tens hours, the excimer laser crystallization is a method in which the silicon layer is locally heated and crystallized at the high temperature for a very short time by injecting the excimer laser to the silicon layer, the metal induced crystallization is a method in which a phenomenon where amorphous silicon induces phase transformation of polysilicon by using the metal by contacting or injecting metal such as nickel, palladium, gold, aluminum and the like to the amorphous silicon layer is used, and the metal induced lateral crystallization is a method for crystallizing the silicon layer by using a method in which the metal and silicon are reacted with each other and crystallization of silicon is induced sequentially while the generated silicide is continuously transported to the side. However, in the present embodiments, the crystallization method is not limited.

In the present embodiments, when the semiconductor layer 125 is formed by patterning the polysilicon layer, the length L₂ of the semiconductor layer 125 is longer than the length L₁ in the range of the source electrode to the drain electrode that is formed by the following process, and the width W₂ of the semiconductor layer 125 is larger than the width W₁ of the source electrode or drain electrode.

On the front surface of the substrate that includes the semiconductor layer, an insulation film such as silicon oxide film or silicon nitride film is formed and patterned to form the etch stopper 126.

The semiconductor layer 125 at a lower portion of the region where the etch stopper 126 is formed is defined by a channel region.

On the substrate that includes the etch stopper 126, the silicon layer into which the high concentration impurity is injected is formed and patterned to define the source/drain region 127, and the source/drain electrode formation material is formed and patterned to form the source/drain electrode 128. However, even though it is not shown in the drawings, after the silicon layer material into which the high concentration impurity is injected and the source/drain electrode formation material are sequentially formed, the source/drain region and source/drain electrode may be simultaneously formed by simultaneously etching the silicon layer into which the high concentration impurity is injected and the source/drain electrode formation material.

When the silicon layer into which the high concentration impurity is injected or the source/drain electrode formation material is etched, the etch stopper functions to prevent the semiconductor layer (particularly, channel region) from being etched or damaged. As described above, a process for forming the source/drain electrode and source/drain region by etching the source/drain electrode formation material and the silicon layer into which the high concentration impurity is injected using the etch stopper is called E/S (Etch Stopper) etching process.

Thereby, a bottom gate type thin film transistor according to the first exemplary embodiment may be manufactured.

As described above, the length L₂ of the semiconductor layer 125 is longer than the length L₁ in the range of the source electrode to the drain electrode, and the width W₂ of the semiconductor layer 125 is larger than the width W₁ of the source electrode or drain electrode. In the present embodiments, the length L₁ in the range of the source electrode to the drain electrode means the longest length of the lengths in the range of an end of the source electrode to an end of the drain electrode.

In the present embodiments, since the length and the width of the semiconductor layer are larger than the longest length among the lengths in the range of an end of the source electrode to an end of the drain electrode and the width of the source/drain electrode, the source/drain electrode is formed in the range of the region on which the semiconductor layer is formed.

In the bottom gate type thin film transistor that has a general structure, since the width of the semiconductor layer is smaller than the width of the source electrode or drain electrode and the length of the semiconductor layer is smaller than the length from the source electrode to the drain electrode, as shown in the R1 region of FIG. 1B and the R2 region of FIG. 1C, the region where the semiconductor layer does not exist is formed at the lower portion of the source electrode or drain electrode, in this region, the MIM (Metal-Insulator-Metal) structure by the layered structure of the gate electrode, gate insulating layer and source/drain electrode exists in the element, so that in the case of when gate voltage is applied to this portion, charge trap and the like occur in the gate insulating layer, thereby causing a problem in terms of reliability.

However, in the present embodiments, since the source/drain electrode is formed in the range of the region where the semiconductor layer is formed, as shown in the R3 region of FIG. 2B and the R4 region of FIG. 2C, it has a structure in which the semiconductor layer 125 is inserted into all regions between the gate electrode 123 and the source/drain electrode 128, so that the MIM (Metal-Insulator-Metal) structure by the layered structure of the gate electrode, gate insulating layer and source/drain electrode like the general structure does not exist in the element.

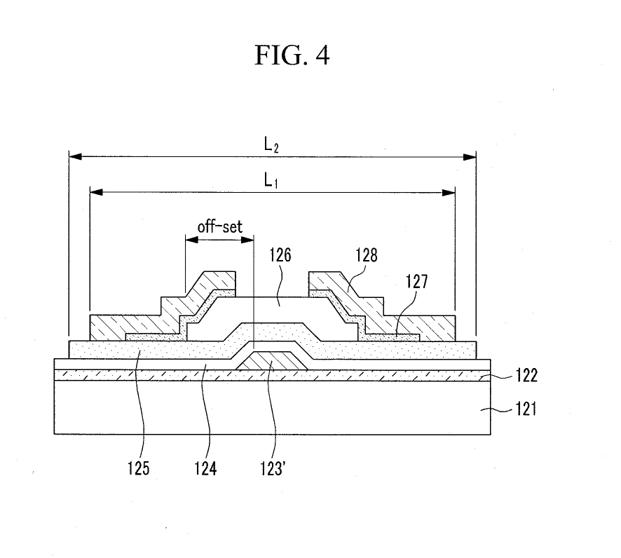

Meanwhile, FIG. 4 is an exemplary variation of a bottom gate type thin film transistor according to the first exemplary embodiment.

As shown in FIG. 4, an offset region may be formed by forming the etch stopper 126 so that the length of the etch stopper is larger than the length of the gate electrode 123′. The offset region means the length in the range of an end of the gate electrode to the region in which the source/drain region at the lower portion of the source/drain electrode is contacted with the semiconductor layer. Basically, the offset region is not doped, and may include LDD (lightly doped drain) or LDS (lightly doped source) region. Since this is apparent to the art, a detailed description thereof will be omitted.

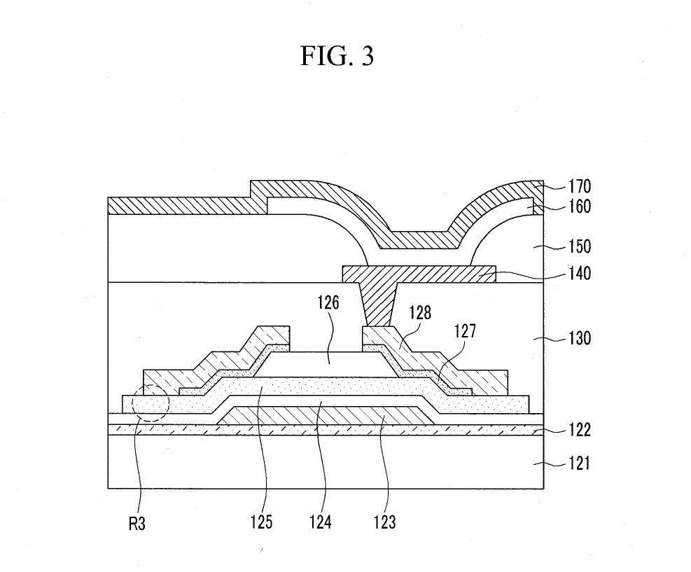

FIG. 3 is a cross-sectional view of an organic light emitting diode (OLED) display that includes a bottom gate type thin film transistor according to the first exemplary embodiment.

Referring to FIG. 3, an insulation film 130 is formed on the front surface of the substrate 121 that includes the thin film transistor according to the first exemplary embodiment. The insulation film 130 may be formed by using any one of silicon oxide film, silicon nitride film or spin on glass film that are inorganic films, or any one of polyimide, benzocyclobutene series resin or acrylate that are organic films. In addition, it may be formed with the layered structure of the inorganic film and the organic film.

By etching the insulation film 130, a via hole that exposes the source electrode or drain electrode 128 is formed. Through the via hole, the first electrode 140 that is connected to any one of the source or drain electrode is formed. The first electrode 140 may be formed with the anode or cathode. In the case of when the first electrode 140 is the anode, the anode may comprise a transparent conductive layer that is made of any one of ITO, IZO or ITZO, and in the case of when the first electrode 140 is the cathode, the cathode may be formed by using Mg, Ca, Al, Ag, Ba or an alloy thereof.

Subsequently, on the first electrode 140, a pixel defining film 150 that has an opening exposing a portion of the first electrode is formed, and on the exposed first electrode, an organic film layer 150 that includes the emission layer is formed. The organic film layer 160 may further include one or plural layers that are selected from the group consisting of a hole injection layer (HIL), a hole transport layer (HTL), a hole suppress layer, an electron suppress layer, an electron injection layer (EIL) and an electron transport layer (ETL). The second electrode 170 is formed on the organic film layer. The second electrode 170 may comprise anode or cathode, in the case of when the second electrode 170 is the anode, the anode may comprise a transparent conductive layer that is made of any one of ITO, IZO or ITZO, and in the case of when the second electrode 170 is the cathode, the cathode may be formed by using Mg, Ca, Al, Ag, Ba or an alloy thereof. Thereby, the organic light emitting diode (OLED) display is accomplished.

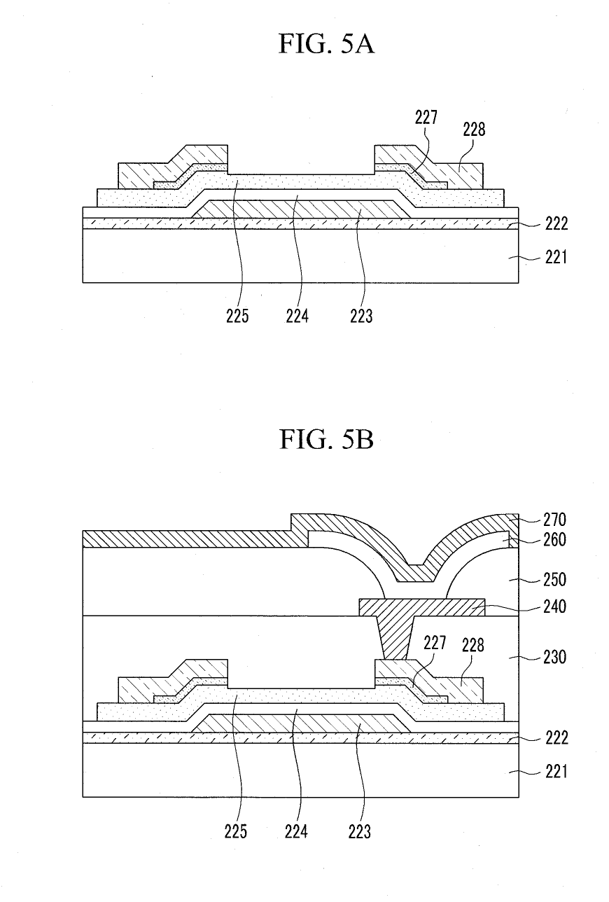

FIG. 5A is a cross-sectional view of a bottom gate type thin film transistor according to the second exemplary embodiment, and FIG. 5B is a cross-sectional view of an organic light emitting diode (OLED) display that includes a bottom gate type thin film transistor according to the second exemplary embodiment.

The bottom gate type thin film transistor and the organic light emitting diode (OLED) display according to the second exemplary embodiment may be the same as the first exemplary embodiment with the exception of the following description.

Referring to FIG. 5A, after the buffer layer 222 is formed on the transparent insulation substrate 221 such as glass or plastic and the gate electrode formation material is formed on the buffer layer, it is patterned to form the gate electrode 223.

Next, the gate insulating layer 224 that comprises a single layer or a multilayer of silicon oxide film or silicon nitride film is formed on the substrate on which the gate electrode 223 is formed.

After that, after the amorphous silicon layer (not shown) is formed on the gate insulating layer, the polysilicon layer (not shown) is formed by crystallizing it, and the semiconductor layer 225 is formed by patterning the polysilicon layer.

In the second exemplary embodiment, like the first exemplary embodiment, when the semiconductor layer 225 is formed by patterning the polysilicon layer, the length of the semiconductor layer 225 is longer than the length in the range of the source electrode to the drain electrode that is formed by the following process, and the width of the semiconductor layer 225 is larger than the width of the source electrode or drain electrode.

Next, on the substrate, the silicon layer into which the high concentration impurity is injected is formed and patterned to define the source/drain region 227, and the source/drain electrode formation material is formed and patterned to form the source/drain electrode 228. However, even though it is not shown in the drawings, after the silicon layer material into which the high concentration impurity is injected and the source/drain electrode formation material are sequentially formed, the source/drain region and source/drain electrode may be simultaneously formed by simultaneously etching the silicon layer into which the high concentration impurity is injected and the source/drain electrode formation material.

When the source/drain region and source/drain electrode is formed, the channel region is defined by further etching a portion of the semiconductor layer in addition to the silicon layer into which the high concentration impurity is injected and source/drain electrode formation material, and as described above, a process for forming each region by etching a portion of the semiconductor layer, the silicon layer into which the high concentration impurity is injected and source/drain electrode formation material to remove them is called an E/B (Etch Back) etching process.

Thereby, a bottom gate type thin film transistor according to the second exemplary embodiment may be manufactured.

Referring to FIG. 5B, an insulation film 230 is formed on the front surface of the substrate 221 that includes the thin film transistor according to the second exemplary embodiment.

A via hole that exposes the source electrode or drain electrode 228 is formed by etching the insulation film 230, and the first electrode 240 that is connected to any one of the source or drain electrode through the via hole is formed.

On the first electrode 240, a pixel defining film 250 that has an opening exposing a portion of the first electrode is formed, and on the exposed the first electrode, an organic film layer 260 that includes the emission layer is formed. Subsequently, the organic light emitting diode (OLED) display is accomplished by forming the second electrode 270 on the organic film layer.

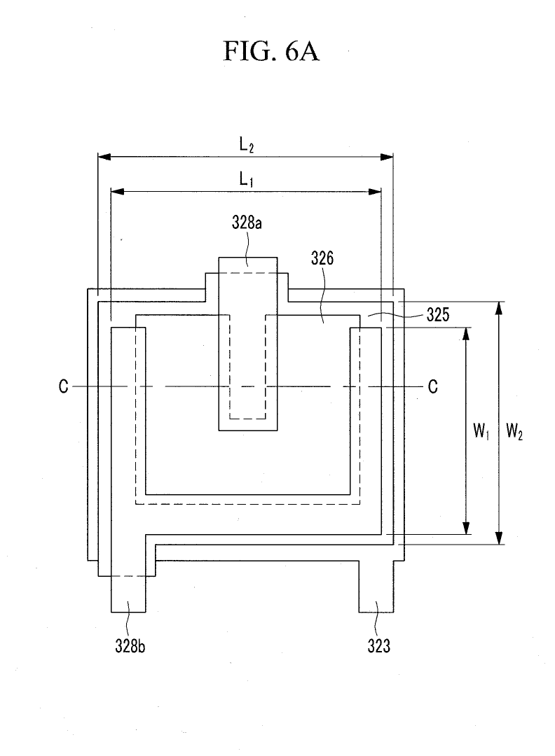

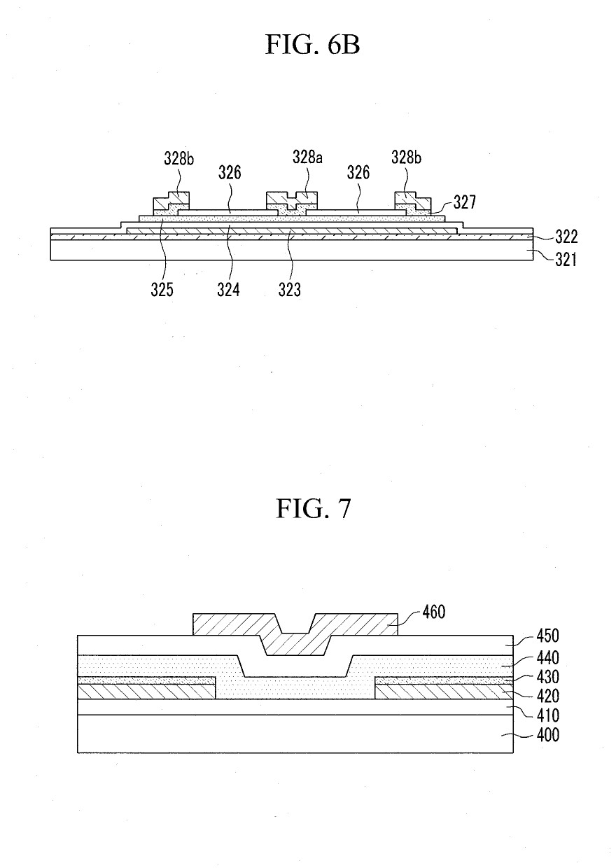

FIG. 6A is a plan view that illustrates a bottom gate type thin film transistor according to the third exemplary embodiment, and FIG. 6B is a cross-sectional view that is taken along the line C-C of FIG. 6A.

The bottom gate type thin film transistor and the organic light emitting diode (OLED) display according to the third exemplary embodiment may be the same as the first exemplary embodiment with the exception of the following description.

Referring to FIG. 6A to FIG. 6B, after the buffer layer 322 is formed on the transparent insulation substrate 321 such as glass or plastic and the gate electrode formation material is formed on the buffer layer, it is patterned to form the gate electrode 323.

The gate insulating layer 324 that comprises a single layer or a multilayer of silicon oxide film or silicon nitride film is formed on the substrate on which the gate electrode 323 is formed, and the amorphous silicon layer (not shown) is formed on the gate insulating layer.

The polysilicon layer (not shown) is formed by crystallizing the amorphous silicon layer, and the semiconductor layer 325 is formed by patterning the polysilicon layer.

On the front surface of the substrate that includes the semiconductor layer, an insulation film such as silicon oxide film or silicon nitride film is formed and patterned to form the etch stopper 326.

The semiconductor layer 325 at a lower portion of the region where the etch stopper 326 is formed is defined by a channel region.

Subsequently, on the substrate that includes the etch stopper 326, the silicon layer into which the high concentration impurity is injected is formed and patterned to define the source/drain region 327, and the source/drain electrode formation material is formed and patterned to form the source electrode 328a and drain electrode 328b.

As shown in FIG. 6A, the source electrode 328a and drain electrode 328b are constituted so that the source electrode is disposed in the central region of the semiconductor layer and the drain electrode surrounds the source electrode in a U form in the external region of the semiconductor layer, thereby improving the width of the channel region.

In the third exemplary embodiment, since the drain electrode surrounds the source electrode, the source electrode is disposed in the drain electrode, and the source electrode is formed in the range of the region where the semiconductor layer is formed.

Therefore, in the third exemplary embodiment, a position relation between the drain electrode and the semiconductor layer is important, the length L₂ of the semiconductor layer 325 is longer than the length L₁ of the drain electrode, and the width W₂ of the semiconductor layer 325 is larger than the width W₁ of the drain electrode. In the present embodiments, the length L₁ of the drain electrode means the longest length among the lengths in the range of an end of the drain electrode to another end of the drain electrode, and the width W₁ of the drain electrode means the largest width among the widths in the range of an end of the drain electrode to another end of the drain electrode.

In the third exemplary embodiment, since the source electrode is disposed in the drain electrode and the length and width of the semiconductor layer are larger than the length and width of the drain electrode, respectively, the source/drain electrode is formed in the range of the region where the semiconductor layer is formed, such that it has a structure in which the semiconductor layer 325 is inserted into all regions between the gate electrode 323 and the source/drain electrode 328a and 328b.

FIG. 7 is a cross-sectional view that illustrates a staggered type thin film transistor according to the fourth exemplary embodiment. The thin film transistor according to the fourth exemplary embodiment may be the same as the first exemplary embodiment with the exception of the following description.

Referring to FIG. 7, after the buffer layer 410 is formed on the transparent insulation substrate 400 such as glass or plastic and the source/drain electrode formation material is formed on the buffer layer, it is patterned to form the source/drain electrode 420.

The source/drain region 430 that comprises silicon into which the high concentration impurity is injected is formed on the source/drain electrode 420, and the amorphous silicon layer (not shown) is formed on the substrate that includes the source/drain region.

The polysilicon layer (not shown) is formed by crystallizing the amorphous silicon layer, and the semiconductor layer 440 is formed by patterning the polysilicon layer.

The source/drain electrodes are formed in a range of a region in which the semiconductor layer is formed. Accordingly, it has a structure in which the semiconductor layer is inserted into all regions between the gate electrode and the source/drain electrode as described later.

The gate insulating layer 450 is formed on the front surface of the substrate that includes the semiconductor layer, and the gate electrode 460 is formed on the gate insulating layer 450.

Thereby, a staggered type thin film transistor according to the fourth exemplary embodiment may be manufactured.

Hereinafter, an improvement of reliability of the bottom gate type thin film transistor according to the present embodiments will be described.

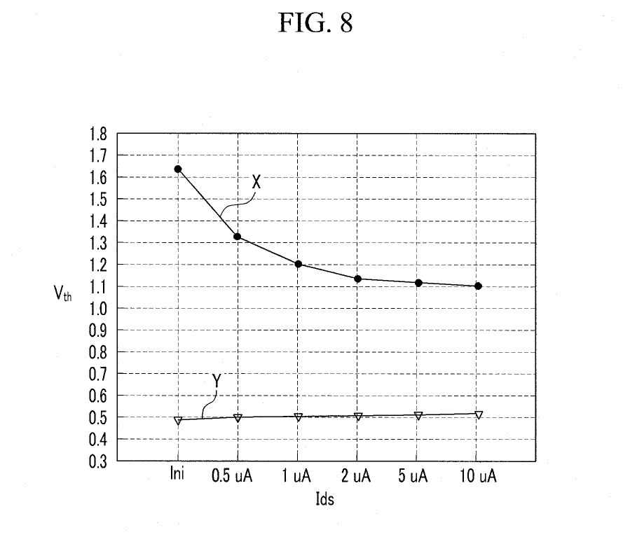

FIG. 8 is a graph that illustrates a change in threshold voltage (Vth) according to a change in source/drain current (Ids).

FIG. 8 shows a graph that measures a change in threshold voltage (ΔVth) after the source drain voltage (Vds) of 10 V is applied, source/drain currents (Ids) of 0.5 uA, 1 uA, 2 uA, 5 uA, and 10 uA are set, and the gate voltage (Vg) is applied for 1 hour, and X represents a characteristic of the bottom gate type thin film transistor that has a general structure, and Y represents a characteristic of the bottom gate type thin film transistor according to the present embodiments.

Referring to FIG. 8, in the case of the bottom gate type thin film transistor that has the general structure, it is about 1.11 V when 10 uA is set at an initial voltage (ini) of about 1.65 V, which shows that a change in threshold voltage (ΔVth) corresponds to about −0.54 V. However, in the case of the bottom gate type thin film transistor according to the present embodiments, it is about 0.52 V when 10 uA is set at an initial voltage (ini) of about 0.47 V, which shows that a change in threshold voltage (ΔVth) corresponds to about 0.05 V, such that in the case of the bottom gate type thin film transistor according to the present embodiments, since a change in threshold voltage is little according to a change in source/drain current, the reliability is largely improved.

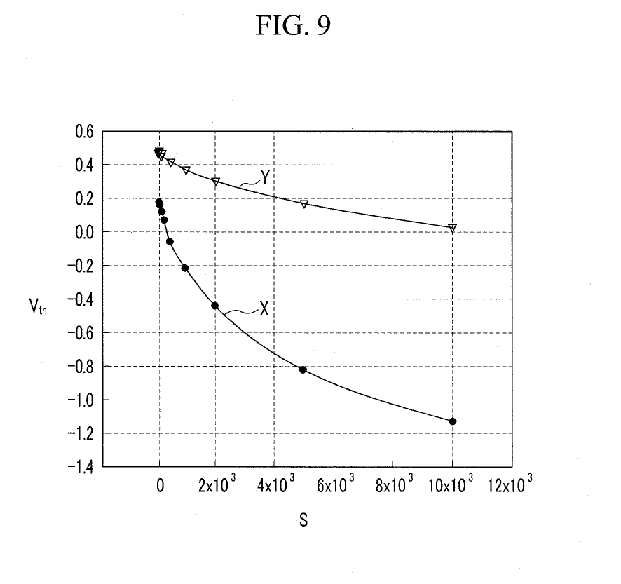

FIG. 9 is a graph that illustrates a change in threshold voltage (Vth) according to time (s).

FIG. 9 is a graph that measures a change in threshold voltage according to time in which only the gate voltage (Vg) of 20 V is applied, and X represents a characteristic of the bottom gate type thin film transistor that has a general structure, and Y represents a characteristic of the bottom gate type thin film transistor according to the present embodiments.

Referring to FIG. 9, in the case of the bottom gate type thin film transistor that has the general structure, it is about −1.11 V when 10*10³ (s) is set at an initial voltage (0) of about 0.19 V, which shows that a change in threshold voltage (ΔVth) corresponds to about −1.3 V. However, in the case of the bottom gate type thin film transistor according to the present embodiments, it is about 0.05 V when 10*10³ (s) is set at an initial voltage (0) of about 0.49 V, which shows that a change in threshold voltage (ΔVth) corresponds to about −0.44 V, such that in the case of the bottom gate type thin film transistor according to the present embodiments, since a change in threshold voltage according to time improves the reliability by about 3 times more than the case of the general structure.

While this disclosure has been described in connection with what is presently considered to be practical exemplary embodiments, it is to be understood that the embodiments are not limited to the disclosed embodiments, but, on the contrary, is intended to cover various modifications and equivalent arrangements included within the spirit and scope of the appended claims.

What is claimed is:

1. A thin film transistor comprising:
a gate electrode, a semiconductor layer and source/drain electrode,
wherein the source/drain electrode is disposed in the region in which the semiconductor layer is formed.

2. The thin film transistor of claim 1, wherein:
the semiconductor layer comprises polysilicon.

3. The thin film transistor of claim 1, further comprising:
source/drain regions that are formed in a predetermined region of an upper portion of the semiconductor layer, wherein the source/drain regions are silicon into which a high concentration impurity has been injected.

4. The thin film transistor of claim 1, further comprising:
source/drain regions that are formed in a predetermined region of a lower portion of the semiconductor layer, wherein the source/drain regions are silicon into which a high concentration impurity has been injected.

5. The thin film transistor of claim 1, further comprising:
an etching preventing layer that is formed in a predetermined region of the semiconductor layer and defines a channel region.

6. A display device comprising the thin film transistor according to claim 1.

7. A display device comprising the thin film transistor according to claim 2.

8. A display device comprising the thin film transistor according to claim 3.

9. A display device comprising the thin film transistor according to claim 4.

10. A display device comprising the thin film transistor according to claim 5.

11. A thin film transistor comprising:
a substrate;
a gate electrode that is disposed on an upper portion of the substrate;
a gate insulating layer that is disposed on the gate electrode;
a semiconductor layer that is disposed on the gate insulating layer;
source/drain regions that are disposed in a predetermined region of an upper portion of the semiconductor layer; and
source/drain electrodes that are electrically connected to the source/drain regions,
wherein the semiconductor layer is inserted into all regions between the gate electrode and the source/drain electrode.

12. The thin film transistor of claim 11, wherein:
the length of the semiconductor layer is longer than the length from the source electrode to the drain electrode.

13. The thin film transistor of claim 12, wherein:
the length from the source electrode to the drain electrode is the longest length of the lengths from an end of the source electrode to an end of the drain electrode.

14. The thin film transistor of claim 11, wherein:
the width of the semiconductor layer is larger than the width of the source electrode or drain electrode.

15. The thin film transistor of claim 11, wherein:
the source electrode is disposed in the central region of the semiconductor layer, and the drain electrode having a U shape surrounds the source electrode in the external region of the semiconductor layer.

16. The thin film transistor of claim 15, wherein:
the length of the semiconductor layer is longer than the length of the drain electrode, and the width of the semiconductor layer is larger than the width of the drain electrode.

17. The thin film transistor of claim 16, wherein:
the length of the drain electrode is the longest length of the lengths from an end of the drain electrode to the other end of the drain electrode, and the width of the drain electrode is the longest width of the widths from an end of the drain electrode to the other end of the drain electrode.

18. A display device comprising the thin film transistor according to claim 7.

19. A thin film transistor comprising:
a substrate;
source/drain electrodes that are disposed on an upper portion of the substrate;
source/drain regions that are disposed on the source/drain electrodes;
a semiconductor layer that is disposed on upper portions of the source/drain regions;
a gate insulating layer that is disposed on an front surface of the substrate that includes the semiconductor layer; and
a gate electrode that is disposed on the gate insulating layer,
wherein the semiconductor layer is inserted into all regions between the gate electrode and the source/drain electrodes.

20. The thin film transistor of claim 19, wherein:
the source/drain electrodes are disposed on a region in which the semiconductor layer is formed.

21. A display device comprising the thin film transistor according to claim 19.
